(19) United States
(12) Patent Application Publication
(10) Pub. No.: US 2021/0351329 A1
(43) Pub. Date: Nov. 11, 2021

(54) RADIATION-EMITTING COMPONENT

(71) Applicant: OSRAM OLED GmbH, Regensburg (DE)

(72) Inventors: Sebastian Stoll, Straubing (DE); Alexander Baumgartner, Donaustauf (DE)

(21) Appl. No.: 17/277,732

(22) PCT Filed: Sep. 17, 2019
(86) PCT No.: PCT/EP2019/074842

§ 371 Date: Mar. 19, 2021

(30) Foreign Application Priority Data
Sep. 19, 2018 (DE) 10 2018 123 010.9

(51) Int. Cl. H01L 33/50; H01L 25/075

(52) U.S. Cl. CPC H01L 33/504; H01L 25/0753

(57) ABSTRACT

A radiation-emitting component may include a first semiconductor chip to emit blue light, a second semiconductor chip to emit cyan-colored light, and a conversion element to emit secondary radiation. The conversion element may be arranged downstream of the first semiconductor chip and the second semiconductor chip. The conversion element emits the secondary radiation under excitation with the blue light of the first semiconductor chip, and the secondary radiation mixes with the blue light to form warm white light.

### CROSS-REFERENCE TO RELATED APPLICATIONS

The present application is a national stage entry according to 35 U.S.C. § 371 of PCT Application No. PCT/EP2019/074842 filed on Sep. 17, 2019; which claims priority to German Patent Application Serial Nos. 10 2018 123 010.9 filed on Sep. 19, 2018; all of which are incorporated herein by reference in their entirety and for all purposes.

### TECHNICAL FIELD

A radiation-emitting component is specified.

It is an object of the present disclosure to specify a radiation-emitting component that is particularly flexible in its application.

### BACKGROUND

During operation, the radiation-emitting component emits electromagnetic radiation, in particular light. The radiation-emitting component may be designed to generate white light during operation. The radiation-emitting component can, for example, be used as a light source in a luminaire. It is also possible that the radiation-emitting component itself forms a luminaire.

### SUMMARY

According to at least one embodiment of the radiation-emitting component, the radiation-emitting component comprises a first semiconductor chip which emits blue light during operation. The first semiconductor chip is, for example, a luminescent diode chip such as a laser diode chip or a light-emitting diode chip. During operation, the first semiconductor chip generates blue light directly in an active region of a semiconductor body. This means that the first semiconductor chip generates the blue light during operation without the use of a phosphor. This makes it possible that the blue light is emitted with a particularly narrow spectral half-width. The blue light has a peak wavelength at which the intensity of the blue light is at its maximum. For example, the peak wavelength of the blue light is between at least 450 nm and at most 478 nm.

According to at least one embodiment of the radiation-emitting component, the radiation-emitting component comprises a second semiconductor chip which emits cyan-colored light during operation. The second semiconductor chip is, for example, a luminescent diode chip such as a laser diode chip or a light-emitting diode chip. During operation, the second semiconductor chip generates cyan-colored light directly in an active region of a semiconductor body. This means that the second semiconductor chip generates the cyan-colored light during operation without the use of a phosphor. This makes it possible that the cyan-colored light is emitted with a particularly narrow spectral half-width. The cyan-colored light has a peak wavelength at which the intensity of the cyan-colored light is at its maximum. For example, the peak wavelength of the cyan-colored light is between at least 480 nm and at most 490 nm.

According to at least one embodiment of the radiation-emitting component, the component comprises a conversion element which emits secondary radiation during operation. The conversion element comprises at least one phosphor or consists of at least one phosphor. The conversion element is excited with a primary radiation and emits the secondary radiation, which is of lower energy than the primary radiation.

According to at least one embodiment of the radiation-emitting component, the conversion element is arranged downstream of the first semiconductor chip. This means that the conversion element follows the first semiconductor chip, for example in a radiation direction of the blue light, so that blue light from the first semiconductor chip at least partially enters the conversion element. It is possible, for example, that the first semiconductor chip is embedded in the conversion element or that the conversion element follows the first semiconductor chip at a radiation exit surface of the semiconductor chip directly or at a distance.

According to at least one embodiment of the radiation-emitting component, the conversion element emits the secondary radiation under excitation with the blue light of the first semiconductor chip. This means that the at least one phosphor of the conversion element is configured to at least partially absorb the blue light and to re-emit the low-energy secondary radiation. For example, the first semiconductor chip and the conversion element are matched to each other so that the peak wavelength of the blue light is in the range of the maximum absorption of the at least one phosphor of the conversion element.

According to at least one embodiment of the radiation-emitting component, the secondary radiation of the conversion element mixes with the blue light to form warm white light. This means that the conversion element is designed to emit warm white light when excited with the blue light. Phosphors for corresponding conversion elements are described, for example, in publications WO 2011/020751 A1, WO 2011/020756 A1 and WO 2013/056895 A1. The disclosure of these publications is hereby expressly included by reference.

According to at least one embodiment of the radiation-emitting component, the component comprises a first semiconductor chip which emits blue light during operation, a second semiconductor chip which emits cyan-colored light during operation, a conversion element which emits secondary radiation during operation. The conversion element is arranged downstream of the first semiconductor chip, the conversion element emits the secondary radiation under excitation with the blue light of the first semiconductor chip, and the secondary radiation mixes with the blue light to form warm white light.

According to at least one embodiment of the radiation-emitting component, the component is configured to emit mixed light from the warm white light and the cyan-colored light during operation. A mixing of the warm white light with the cyan-colored light can be achieved, for example, by means of an optical element which is arranged downstream of the first semiconductor chip, the second semiconductor chip and the conversion element. Furthermore, it is possible that the light mixing is achieved by arranging the conversion element downstream of the first semiconductor chip and the second semiconductor chip. In this way, the conversion element can not only serve to generate secondary radiation, but also causes the warm white light to be mixed with the cyan-colored light of the second semiconductor chip.

According to at least one embodiment of the radiation-emitting component, the first semiconductor chip and the second semiconductor chip can be operated independently of one another. This means that in the radiation-emitting semiconductor component either the first semiconductor chip can be operated or the second semiconductor chip can be operated or the first semiconductor chip and the second semiconductor chip can be operated at the same time.

This may be done, for example, by a control device which may be part of the radiation-emitting component or which is arranged separately from the radiation-emitting component and is configured to operate at least one radiation-emitting component.

According to at least one embodiment of the radiation-emitting component, the color temperature of the mixed light is adjustable. This means that the color temperature of the mixed light can be selected from at least two values. Furthermore, it is possible that the color temperature of the mixed light can be selected from more than two values or that the color temperature of the mixed light is quasi infinitely variable.

It has been found that radiation-emitting components are advantageous where the correlated color temperature (the color temperature for short) of the emitting white light is adjustable. It is advantageous if the color temperature can be changed within a definable temperature range without causing inhomogeneities regarding the chromaticity coordinate distribution over a light-emitting surface of the radiation-emitting component. Furthermore, it is advantageous if the color temperature is tuned within the component, so that no adaptation by an external optical element is necessary.

It has been shown that by using a cyan-colored second semiconductor chip in combination with a first semiconductor chip and a conversion element, which together emit warm white light, the color temperature can be changed and adjusted while maintaining a high color rendering value.

By operating the second semiconductor chip, which emits cyan-colored light during operation, it is possible to shift the color temperature towards cold white light. This means that the greater the intensity with which the second semiconductor chip is operated compared to the first semiconductor chip, or the greater the power with which the second semiconductor chip is operated compared to the first semiconductor chip, the more the color temperature can be shifted into the cold white range.

According to at least one embodiment of the radiation-emitting component, the color temperature of the mixed light is adjustable between a lowest value and a highest value, the difference between the lowest value and the highest value being at least 1500 K.

For the lowest value of the color temperature of the mixed light, for example, the cyan-colored second semiconductor chip is not operated to generate warm white light. For the highest value and thus cold white light, it is possible, for example, to operate the second semiconductor chip at maximum power or maximum intensity. The first semiconductor chip, which emits blue light during operation and which mainly excites the conversion element, can either always be operated with the same intensity or power, or the intensity and/or power with which the first semiconductor chip is operated is reduced towards the highest value to change the color temperature. Depending on the ratio of the intensities and/or power with which the first semiconductor chip and the second semiconductor chip are operated, the color temperature and thus the color location of the emitted mixed light can be adjusted continuously or quasi-continuously. “Quasi continuous” here means that the change in color temperature occurs in such a way that it is barely perceptible to the human observer.

For example, a lowest value for the color temperature of mixed light is 3000 K and a highest value for the color temperature of mixed light is 5000 K.

According to at least one embodiment of the radiation-emitting component, the conversion element is arranged downstream of the second semiconductor chip. For this purpose, for example, the first semiconductor chip and the second semiconductor chip can be embedded in the conversion element. In this case, the radiation-emitting component is particularly compact, since both optoelectronic semiconductor chips are embedded in the same conversion element. The conversion element then also serves to mix the cyan-colored light with the warm-white light, making further mixing optics unnecessary. In particular, it is possible that the cyan-colored light is hardly or not at all converted when passing through the conversion element. For example, a maximum of 10%, and in particular a maximum of 5% of the cyan-colored light relative to its energy is converted by the conversion element to light of longer wavelengths. The conversion element is in particular transparent for the cyan-colored light.

According to at least one embodiment of the radiation-emitting component, the first semiconductor chip, the second semiconductor chip and the conversion element are arranged in a common housing. The housing has, for example, a cavity at the bottom of which the first semiconductor chip and the second semiconductor chip are arranged. In the cavity, the semiconductor chips can be surrounded and covered by the conversion element so that they are embedded in the conversion element. Advantageously, in this case a mixing of the warm white light and the cyan-colored light to form the mixed light can take place in the housing. For this purpose, the housing can, for example, have inner surfaces facing the semiconductor chips and the conversion element which are designed to reflect the cyan-colored and the warm white light.

According to at least one embodiment of the radiation-emitting component, the second semiconductor chip comprises an active region which is configured to emit electromagnetic radiation with a peak wavelength between at least 480 nm and at most 490 nm. This means that the cyan-colored light is generated directly by the semiconductor chip without the use of an additional conversion element or an additional phosphor. This also allows a particularly compact design of the radiation-emitting component.

A radiation-emitting component described here offers, among other things, the advantage that the color temperature can be changed within the device. This has the advantage that only one light-emitting surface, for example an exposed outer surface of the conversion element, has to be considered for all color temperatures and chromaticity coordinates. Thus, the optical system which is arranged downstream of the radiation-emitting component can be designed in a particularly simple way.

In addition, there is no local separation of the color temperature for the mixed light. This means that the radiation-emitting component can emit light of the same color temperature homogeneously over the entire light-emitting outer surface. This is particularly advantageous if additional optical elements are to be arranged downstream of the radiation-emitting component, since these can thus be optimized to a single light-emitting surface. Furthermore, additional mixing optics can be dispensed with.

Overall, the number of radiation-emitting components and optics can be reduced by mixing the light to form mixed light within the component.

Furthermore, the radiation-emitting component is particularly easy to control, since the color temperature of the mixed light can, for example, depend exclusively on the current supply to the second semiconductor chip.

### BRIEF DESCRIPTION OF THE DRAWINGS

In the following, a radiation-emitting component described here is explained in more detail by means of non-limiting embodiments and the associated figures.

FIG. 1 shows an exemplary embodiment of a radiation-emitting component described here by means of a schematic sectional view.

On the basis the graphic applications of FIGS. 2, 3 and 4, exemplary embodiments of radiation-emitting components described here are explained in more detail.

Identical, similar or equivalent elements are provided with the same reference signs in the figures. The figures and the proportions of the elements represented in the figures among each other are not to be considered as true to scale. Rather, individual elements may be oversized for better representability and/or for better comprehensibility.

### DETAILED DESCRIPTION

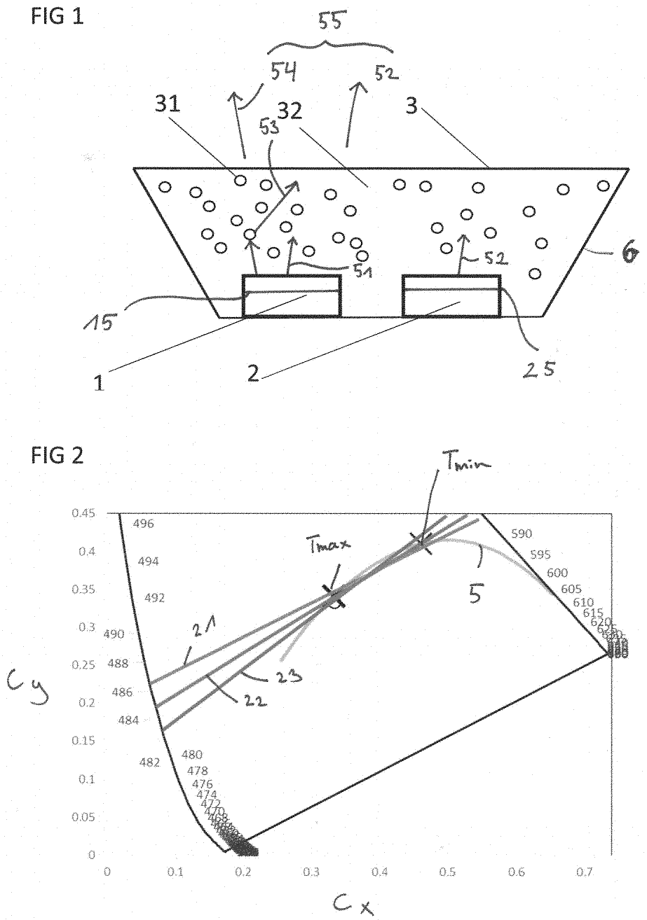

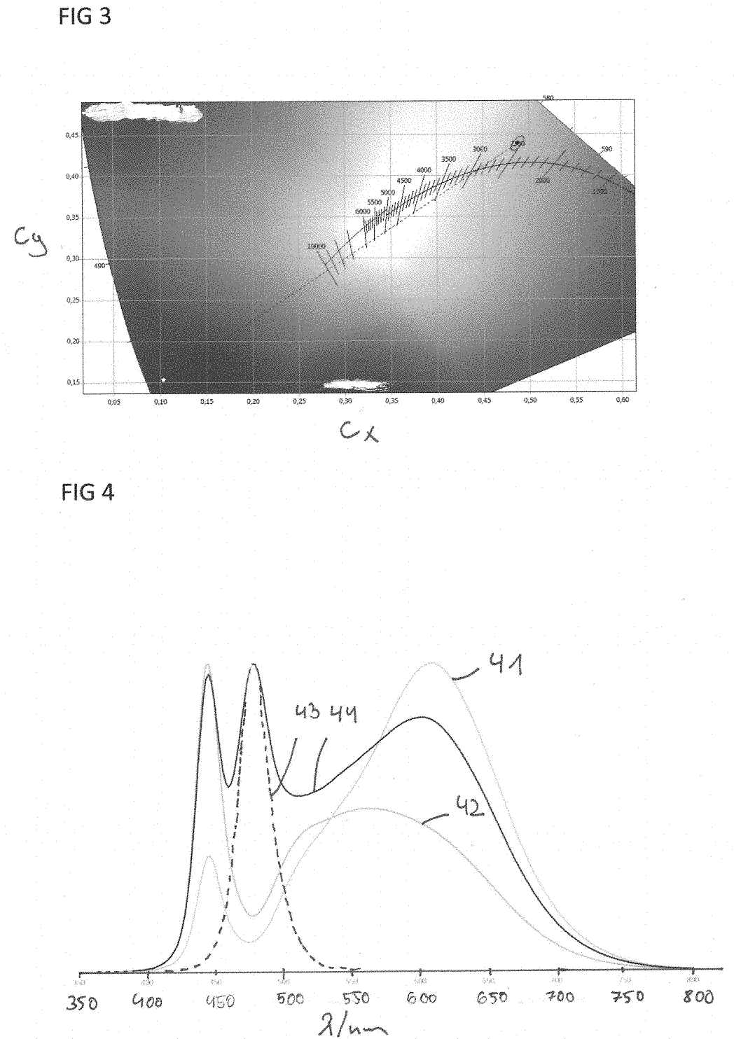

The radiation-emitting component of the exemplary embodiment in FIG. 1 comprises a first semiconductor chip 1 which emits blue light during operation. The blue light, for example, has a peak wavelength that can be around 475 nm, compare for example the left peak of spectrum 44 in FIG. 4.

The first semiconductor chip generates the blue light 51 directly, for example in an active region 15.

The radiation-emitting component further comprises a second semiconductor chip which emits cyan-colored light 52 from an active region 25 during operation. The two radiation-emitting semiconductor chips 1, 2 are arranged in a housing 6. Further, they are surrounded by the conversion element 3. The conversion element 3 comprises a matrix material 32, which is formed, for example, with a translucent plastic material such as epoxy resin and/or silicone. Particles of a phosphor 31 are incorporated into the matrix material 32.

The blue light 51 hits the phosphor 31, producing secondary radiation 53. The secondary radiation 53 and the blue light 51 mix in the conversion element 3 to form the warm white light 54. The warm white light 54 can mix with the cyan-colored light 52 in the conversion element 3 to form the mixed light 55, whose color temperature is adjustable.

The adjustment of the color temperature is explained in more detail by means of FIG. 2, for example. FIG. 2 shows a CIE CX,CY diagram with the Planck curve 5. The diagram shows a first conversion line 21 for a second semiconductor chip 2, which emits cyan-colored light with a peak wavelength of approximately 487 nm. Furthermore, a second conversion line 22 is drawn for cyan-colored light with a peak wavelength of about 485 nm. Finally, a third conversion line 23 is drawn for cyan-colored light with a peak wavelength of about 482 nm.

As can be seen from the illustration in FIG. 2, second semiconductor chips 2 of different peak wavelengths can be used to select different ranges for adjusting the color temperature. The color temperature can be adjusted between the values Tmin and Tmax, which are determined by the intersection points of the conversion line with the Planck curve 5. For the second conversion line 22, for example, the color temperature can be adjusted between Tmin of about 3000 K and Tmax of about 5000 K.

This requires a phosphor mixture for the conversion element 3 which, together with the light 51 of the first semiconductor chip, emits warm white light.

FIG. 3 schematically shows an application corresponding to FIG. 2 for a fourth conversion line 24, where the peak wavelength of the second semiconductor chip 2 is 480 nm. With such cyan-colored light, it is possible to produce particularly cold white light of high color temperature.

FIG. 4 shows different spectra for explanation. Spectrum 41 is the spectrum of warm white light produced with the first semiconductor chip and the conversion element 3. In comparison, spectrum 42 shows a spectrum for cold white light produced with the first semiconductor chip 1 and a phosphor mixture for the production of cold white light. Spectrum 43 is the spectrum of a second semiconductor chip 2 with a peak wavelength at 482 nm. Spectrum 44 shows a superposition of spectrum 42 with spectrum 43.

The features and exemplary embodiments described in connection with the figures can be combined with each other according to further exemplary embodiments, even if not all combinations are explicitly described. Furthermore, the exemplary embodiments described in connection with the figures may alternatively or additionally have further features as described in the general part.

This patent application claims the priority of German patent application 102018123010.9, the disclosure content of which is hereby incorporated by reference.

The invention is not limited to the exemplary embodiments by the description based on the same. Rather, the invention comprises any new feature as well as any combination of features, which in particular includes any combination of features in the claims, even if this feature or this combination itself is not explicitly stated in the claims or exemplary embodiments.

### LIST OF REFERENCE SIGNS

1 first semiconductor chip (blue)
15 active region
2 second semiconductor chip (cyan)
21 first conversion line
22 second conversion line
23 third conversion line
24 fourth conversion line
25 active region
3 conversion element
31 phosphor
32 matrix material
41 spectrum of warm white light generated by the first semiconductor chip 1
42 spectrum of cold white light generated by the first semiconductor chip 1
43 spectrum of the second semiconductor chip 2
44 spectrum of the superposition of spectrum 42 with spectrum 43
5 Planck curve
51 blue light
52 cyan-colored light
53 secondary radiation
54 warm white light
55 mixed light
6 housing
Tmin lowest value of color temperature
Tmax highest value of color temperature

1. A radiation-emitting component comprising:
a first semiconductor chip configured to emit blue light;
a second semiconductor chip configured to emit cyan-colored light; and
a conversion element configured to emit secondary radiation;
wherein:
the conversion element is arranged downstream of the first semiconductor chip and the second semiconductor chip;
the conversion element is configured to emit the secondary radiation under excitation with the blue light of the first semiconductor chip;
a maximum of 10% or less of the cyan-colored light is converted when passing through the conversion element; and
the secondary radiation mixes with the blue light to form warm white light.

2. The radiation-emitting component according to claim 1,
wherein the radiation-emitting component is configured to emit mixed light from the warm white light and the cyan-colored light.

3. The radiation-emitting component according to claim 1,
wherein the first semiconductor chip and the second semiconductor chip are operated independently of one another.

4. The radiation-emitting component according to claim 1,
wherein the color temperature of the mixed light is adjustable.

5. The radiation-emitting component according to claim 1,
wherein the color temperature of the mixed light is adjustable between a lowest value (Tmin) and a highest value (Tmax), the difference between the lowest value (Tmin) and the highest value (Tmax) being at least 1500 K.

6. The radiation-emitting component according to claim 1,
wherein the conversion element supports or causes a mixing of the warm white light with the cyan-colored light.

7. The radiation-emitting component according to claim 1,
wherein the first semiconductor chip and the second semiconductor chip are embedded in the conversion element.

8. The radiation-emitting component according to claim 1,
wherein the first semiconductor chip, the second semiconductor chip and the conversion element are arranged in a common housing.

9. The radiation-emitting component according to claim 8,
wherein the warm white light and the cyan-colored light form a mixed light in the housing.

10. The radiation-emitting component according to claim 1,
wherein the second semiconductor chip has an active region configured to emit electromagnetic radiation with a peak wavelength 480 nm to 490 nm.

11. A radiation-emitting component comprising
a first semiconductor chip configured to emit blue light,
a second semiconductor chip configured to emit cyan-colored light, and
a conversion element configured to emit secondary radiation,
wherein:
the conversion element is arranged downstream of the first semiconductor chip and the second semiconductor chip,
the conversion element emits the secondary radiation under excitation with the blue light of the first semiconductor chip, and
the secondary radiation mixes with the blue light to form warm white light.
